(19) United States
(12) Patent Application Publication
(10) Pub. No.: US 2026/0342326 A1
(43) Pub. Date: Oct. 29, 2026

(54) CIRCUIT FOR PROVIDING A SUPPLY CURRENT AND METHOD THEREFORE

(71) Applicant: ams-OSRAM AG, Premstaetten (AT)

(72) Inventors: Carlo FIOCCHI, Belgioioso (IT); Marco CROCE, Orio Litta (IT)

(21) Appl. No.: 19/117,968

(22) PCT Filed: Sep. 15, 2023
(86) PCT No.: PCT/EP2023/075401

§ 371 Date: Apr. 3, 2025

(30) Foreign Application Priority Data
Oct. 7, 2022 (DE) 10 2022 125 887.4

(51) Int. Cl. H03K 17/042; H05B 45/345

(52) U.S. Cl. CPC H03K 17/04206; H05B 45/345

(57) ABSTRACT

The disclosure relates to a circuit (10) for providing a supply current, the circuit comprising a current generator (100) for generating a constant current (Iref), a ramp generator (110) for generating a current ramp, the current ramp being subtracted from the constant current (Iref) to generate the supply current. The circuit (10) further comprises a comparing circuit (120) for comparing the supply current with a first current value (Ires), a clamping switch (130) configured to switch off the ramp generator (110) when the supply current is smaller than or equal to the first current value (Ires), and a supply circuit (140) for supplying the supply current to a load (150).

### BACKGROUND

A circuit for generating current pulses may be used in various applications, for example, in the case of a LED it provides a current that is mostly pulsed with a slow pulse wide modulation (PWM) . Overall, PWM signals are applied for dimming LEDS, controlling motors, and various other electronic devices. Control over the average current and voltage delivered to a load (such as a LED) is thereby achieved by rapidly turning on and off a switch between the load and a source. This modulation, however, implies a repetitive pattern of disturbances. To address said issue many approaches have been considered that are based on a reduction of a current pulse's slope, where a constant slope is preferable. That is, generating current pulses rising from a low level to a high level and viceversa with a linear profile is of key interest.

A commonly used circuit for achieving this is that of a ramp generator. The ramp generator creates a linear rising or falling output with respect to time. However, generating a linear ramp requires a large amount of development effort. Accuracy, distortion, and responsiveness are the main challenges to be faced: the ramp should occur in a short time, typically a few tenths of a nanosecond, and the allowed tolerances for the amplitude of the regulated current pulse are quite tight (about 1 to 2% with minimal thermal drift). Incorporating a trimming structure into the ramp generator further complicates the solution and may present a liability because of parasites.

Furthermore, the presence of a switch to turn on and off the current/voltage to a load such as an LED may cause additional side effects.

In addition, to avoid a swinging of the current when starting the ramp procedure, a clamping circuit is implemented. However, combining said concepts sets high restrictions regarding the matching requirements of the respective circuit elements that affect the overall performance and the slope of the output current.

Concepts are therefore being sought for a circuit with a reduced area requirement that enables the generation of current pulses with a defined slope.

It is an object of the present invention to provide an improved circuit.

### SUMMARY

According to embodiments, a circuit for providing a supply current comprises a current generator for generating a constant current, a ramp generator for generating a current ramp, the current ramp being subtracted from the constant current to generate the supply current, a comparing circuit for comparing the supply current with a first current value, a clamping switch configured to switch off the ramp generator when the supply current is smaller than or equal to the first current value, and a supply circuit for supplying the supply current to a load.

Said configuration enables controlling the supply current in the circuit by sensing its value via the comparing circuit and clamping the peak of the ramp provided by the ramp generator to generate a small supply current or residual current. Leaving this current in the circuit minimizes a dead-time between a turn-on and rise of the current ramp (e.g., the starting of the ramp procedure and a change of an output current). This results in an improved circuit that prevents current distortions and saves area and design efforts.

In this context, the circuit may further comprise a clamping circuit for determining a lower limit of the current ramp.

Furthermore, the comparing circuit may comprise a sensing mirror comprising a buffer transistor and a buffer mirror transistor. The buffer transistor may be connected in series to the supply circuit, and the buffer mirror transistor may be connected via a connection node to a current source supplying current of the first current value.

The clamping switch may comprise a clamping transistor, a gate of the clamping transistor being connected to the connection node.

The comparing circuit comprising of the buffer transistor and the buffer mirror transistor may allow measuring the supply current. The first current value may be set with high precision to a few μA.

The circuit may supply the supply current of the first current value when the ramp generator is switched off.

The supply circuit may further comprise a supply switching element for turning off the supply current when the supply current is smaller than or equal to the first current value.

In one embodiment, the circuit may also comprise a driving element for driving the supply switching element. The driving element in this configuration is coupled to the clamping switch.

According to embodiments, a method for providing a supply current comprises the following generating a constant current, generating a current ramp, the current ramp being subtracted from the constant current to generate the supply current, comparing the supply current with a first current value, switching off a ramp generator when the supply current is smaller than or equal to the first current value, and supplying the supply current to a load.

Furthermore, a lower limit of the current ramp may be determined.

Furthermore, the supply current of the first current value may be supplied when the ramp generator is switched off. The first current value may be set with high precision to a few μA.

According to embodiments, an illumination device comprises a light emitting element and the above described circuit for providing a supply current to the light emitting element.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1 is a schematic diagram illustrating a circuit for providing a supply current according to embodiments.

FIG. 2A illustrates components of the circuit for providing a supply current in more detail.

FIG. 2B shows examples of waveforms generated by circuit components according to embodiments.

FIG. 3 is a diagram illustrating components of a circuit for providing a supply current according to embodiments.

FIG. 4 is a schematic diagram illustrating a method for providing a supply current according to embodiments.

FIG. 5 is a schematic diagram illustrating an electronic device according to embodiments.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

As employed in this specification, the terms “coupled” and/or “electrically coupled” are not meant to mean that the elements must be directly coupled together-intervening elements may be provided between the “coupled” or “electrically coupled” elements. The term “electrically connected” intends to describe a low-ohmic electric connection between the elements electrically connected together.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

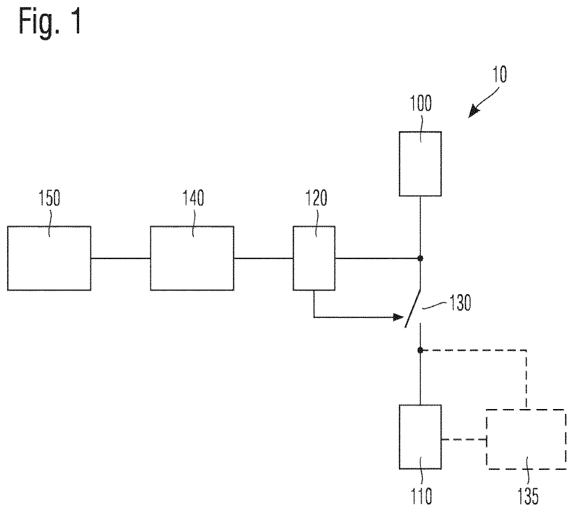

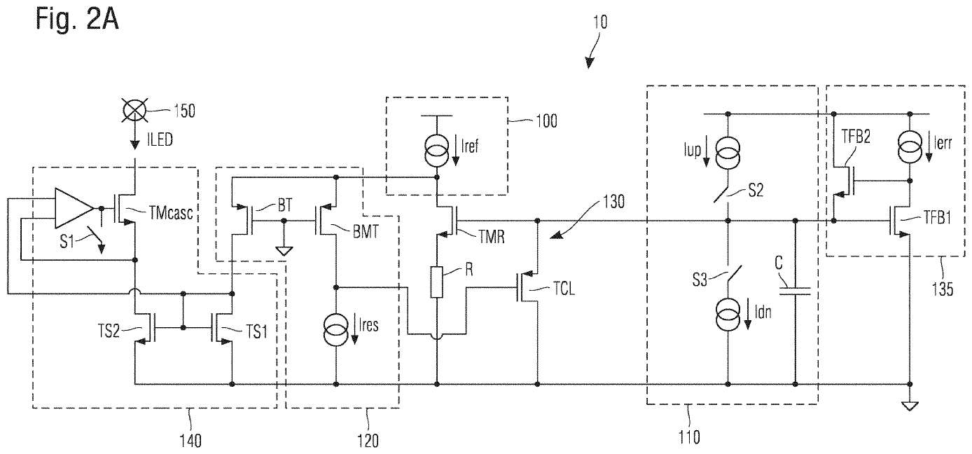

FIG. 1 is a schematic diagram illustrating the general setup of a circuit for providing a supply current 10 according to embodiments. The circuit 10 comprises a current generator 100, a ramp generator 110, a comparing circuit 120, a clamping switch 130, a clamping circuit 135, and a supply circuit 140. The circuit 10 is further used, for example, to provide current pulses to a load 150 such as a LED. FIG. 2 illustrates the components of the circuit 10 in more detail, which are described in the following.

The current generator 100 may comprise a current source that generates a constant (reference) current Iref as indicated by a corresponding arrow in FIG. 2. This current Iref is provided to a terminal of a transistor TMR, which is also a part of the circuit 10. For example, Iref can be set to 5 mA and provided to a source of the transistor TMR, which may be a NMOS transistor.

The ramp generator 110 may comprise two current sources generating currents Iup and Idn, two respective switches S2, S3, and a capacitor C as illustrated in FIG. 2. The two switches S2, S3 alternate the opposed currents Iup and Idn to generate a (voltage−) ramp at a gate of the NMOS transistor TMR. This (voltage−) ramp may be provided to a voltage−to-current converter (e.g., formed by the NMOS transistor TMR connected to a resistor R). In greater detail, the transistor TMR acts in combination with the resistor R, which is coupled to the transistor TMR in series, as a generator that subtracts the ramping current from the constant incoming current Iref to generate the supply current. More specifically, the (voltage−) ramp generated at the gate of the NMOS transistor TMR may shape the current subtracted from a current mirror TS1, TS2, which may be part of the supply circuit 140 described in detail later on.

Such a configuration may ensure that the current supplied to the load 150 has a linear profile when the switches S2 S3 are alternatively brought in conduction.

For example, as described above, the switches S2, S3 are complementary (i.e., alternately turned on and off). Ideally, rising transition at the switch S2 (for example, when turning S2 on) would make the (voltage−) ramp start rising and may start to reduce the supply current. At the same time, at a falling transition at the switch S2 (for example, when turning S2 off), the complementary transition at the switch S3 may decrease the current across the NMOS transistor TMR and the supply current would start increasing.

As the positive and negative (−voltage) ramp may have a slope given by Iup/C and Idn/C, respectively, it follows that the supply current provided to the load 150 has a transition slope given by Iup/(C*R) and Idn/(C*R), respectively.

However, some issues may arise from this approach as explained in the following. In this context FIG. 2B illustrates examples of waveforms.

For example, a gate terminal of the NMOS transistor TMR may start driving a current ITS1 at a voltage slightly larger than zero, when the gate voltage VTMR gate is at approximately the threshold of the NMOS transistor TMR. This means that if the (voltage−) ramp at the gate terminal of the NMOS transistor TMR starts from GND, the supply current through transistor TS1 starts decreasing with a delay (called dead-time at turn off) due to the time it takes for the (voltage−) ramp to reach a threshold of the NMOS transistor TMR. This value may be expressed through C*Vth/Iup.

In addition, the current through NMOS transistor TMR assumes the value Iref when the ramp voltage is at a given value V1, determined by the size of the NMOS transistor TMR, the resistor R and temperature. In case the (voltage−) ramp starts from a different value Vmax, it will take a time C*(Vmax−V1)/Idn (called dead-time at turn on) before the current in the load 150 starts rising from zero.

Adopting the same rise/fall time for the supply current (i.e. Idn=Iup), it follows that the effective duration of the pulse is altered by the value [C*(Vmax−V1)−C*Vth]/Iup.

As will be explained in the following, due to the functionality of the comparing circuit 120 this error is reduced. Hence, accuracy of the definition of the pulse duration may be improved. As a consequence, the initial voltages of the (voltage−) ramp at Vth and V1, respectively, to cancel the dead time values, may be precisely set.

As will be explained in the following, a small supply (or residual) current across the current mirror TS1, TS2 in the OFF status is provided or left. This may systematically improve the dead time at turn on.

According to embodiments, this may be achieved by directly setting the supply (residual) current using the comparing circuit 120. As will be explained, the circuit 120 may sense the supply (residual) current and correspondingly adopt the current through the NMOS transistor TMR as explained in the following.

The comparing circuit 120 compares the supply current with a first current value Ires. The first current value Ires may be set with high precision to a few μA. In one non-limiting example, it may be set to 5 μA.

The clamping switch 130 suppresses the ramping when the supply current is smaller than or equal to the first current value Ires. This results and regulates a supply current that resembles the first current value Ires. The clamping switch 130, shown in simplified form in FIG. 1, may include a clamping transistor TCL. A gate of the clamping transistor TCL may be connected to the connection node, The clamping transistor TCL is described in detail later on.

The regulation or control of the supply current via upper level clamping as described above allows providing a small supply or residual current to the supply circuit 140. This supply current minimizes the dead-time when starting the ramp procedure again.

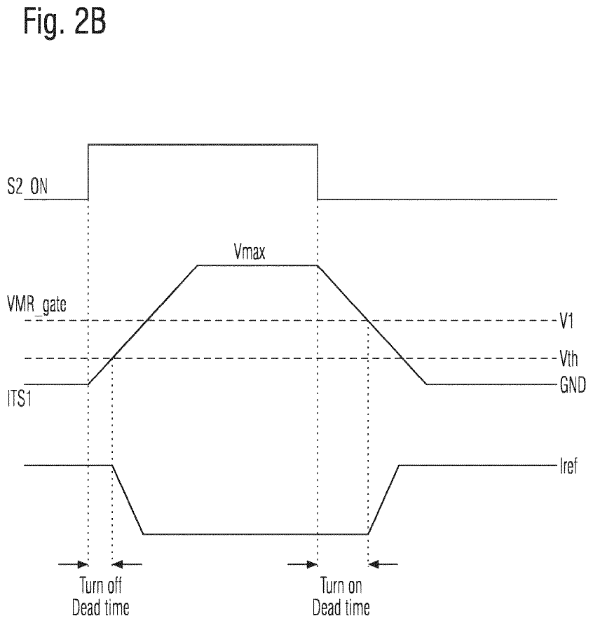

The supply circuit 140 supplies the supply current to the load 150. In detail, the supply circuit 140, which represents a output current branch of the circuit 10, may further include a cascode formed by a transistor TMcasc, a switch S1 that serves as supply switching element, an operational amplifier, and the current mirror in form of two transistors TS1, TS2. The transistors TMcasc, TS1, TS2 may be for example NMOS transistors. The operational amplifier input may be connected as in shown in FIGS. 2A and 3. Therefore, the same voltage at the drains of the current mirror TS1 TS2 may be applied. Hence, accuracy may be improved.

The output current may be turned on and off in the output current branch via the cascode in order to generate current pulses. As discussed above, the dead-time between the start of the ramping procedure and the change of the output current is shortened due to the presence of the small residual current in the output current branch. This current is kept small by sensing its value and clamping it accordingly as described above.

The circuit 10 may further comprise a clamping circuit 135 to determine a lower limit of the current ramp. Said circuit 135 may comprise a current generator generating a current Ierr and transistors TFB1, TFB2. In greater detail, the transistors TFB1, TFB2 clamp the current ramp at the gate of transistor TMR at a low level, i.e. they perform a low level clamping. This guarantees that a minimum current is always flowing across TMR, which further minimizes the dead-time.

The current ramp controls the gate of the transistor TMR as described above. If the current through BMT is large, the clamping transistor TCL is turned off (off condition) and no clamping takes place.

The comparing circuit 120 may comprise a sensing mirror including a buffer transistor BT and a buffer mirror transistor BMT as shown in FIG. 2. The buffer transistor BT may be connected in series to the supply circuit 140. The buffer mirror transistor BMT may be connected in parallel with a current source supplying current of the first current value Ires. Both transistors BT, BMT may be implemented as PMOS transistors. The buffer mirror transistor BMT may be crossed by a scaled down current replica of BT. In case that the current drops below the first current value Ires, the clamping transistor TCL may be turned on, i.e., it becomes conductive. This stops the ramping up of the ramp generator 110 and regulates the supply current as a scaled current replica of Ires across transistor TS1 of the supply circuit 140.

That is, the supply current of the first current value Ires is supplied to the supply circuit 140 when the ramp generator 110 is switched off.

Specifically, the comparing circuit 120 allows measuring or sensing the supply current in order to adapt the current of the transistor TMR accordingly via the clamping switch 130 to ensure that the residual current is sufficiently small.

In addition, the switch S1 of the supply current 140 as shown in FIG. 2 (i.e., the switching element) turns off the supply current in the supply circuit 140 when the supply current is smaller than or equal to the first current value Ires. For example, the switch S1 is opened to prevent the supply current from reaching the load 150, e. g., the LED.

One aspect of the present invention resides in that the residual current flowing through the buffer transistor BT is directly measured and set. On the contrary, the conventional approach measures and sets the current absorbed by the ramp generator by means of TMR transistor, which nearly equals Iref, and obtains the residual one as their difference. As any error due to mismatch results in a percentage of the measured parameter, the accuracy of the residual current is largely improved, even when using small devices and a resistor with a minimum width R. This results in a significant area saving.

Furthermore, only the precision with which the first current value Ires is set and the offsets of the buffer transistor BT and mirror buffer transistor BMT determine the error affecting the residual current. Inaccuracies related to the transistor TMR and resistor R are cancelled. This leads to an error of only a few percent compared to the first current value Ires, even when using small devices and a resistor with a minimum width R. This configuration also saves area, since there is no need for an additional resistor as required in common clamping circuits.

FIG. 3 illustrates another embodiment of the present invention. The circuit 10 shown in FIG. 3 may comprise the same components as the circuit 10 shown in FIG. 2. In addition, it comprises a driving element DE for driving the switching element S1. The driving element DE is coupled to the clamping switch 130. In one example, the switching element S1 may comprise further components. For example, the switch S1 may comprises the operational amplifier as shown in FIGS. 2 and 3. That is, the switch S1 and the amplifier may form a block as indicated by the dashed rectangle in FIG. 3.

In general, the time for turning on S1 is set after the completion of the ramp at the gate of the transistor TMR. Otherwise the current supplied to the load 150 (e.g., the LED) would drop very fast to Zero starting from a too high value. This further complicates controlling the slope of the current pulses. For a safe turn-on timing, a dedicated ramp that is matched to the one ramp across the transistor TMR and which is a bit slower, has to be adopted to set the turn-on time for S1. However, this implies additional area and requires a huge design effort.

Given the circuit 10 as shown in FIG. 3, a simple observation can be made as follows: as soon as the upper clamping is reached, i.e., when the clamping switch 130 turns off the ramp generator 110 (that is, when the clamping transistor TCL starts being crossed by a current and becomes conductive), the residual current flowing through transistor TS1 is sufficiently small (a few μA) such that the switch S1 can be turned on. In greater detail, comparing this current to an arbitrarily small threshold Ithr defines the time to turn the switch S1 on. This allows the removal of the matched ramp while exploiting an already existing circuitry.

This implementation is shown in FIG. 3. As soon as the current across the clamping transistor TCL exceeds the threshold Ithr, a simple comparator of the driving element DE detects the event. The comparator provides a signal to a logic section (not shown in FIG. 3) of the driving element DE to turn the switch S1 on. This is indicated in FIG. 3 by a small arrow that leaves the driving element DE. The presence of the logic section takes also care about the S1 turn-off, which may be carried out with simple sequential gates, which are implemented in commonly known ways.

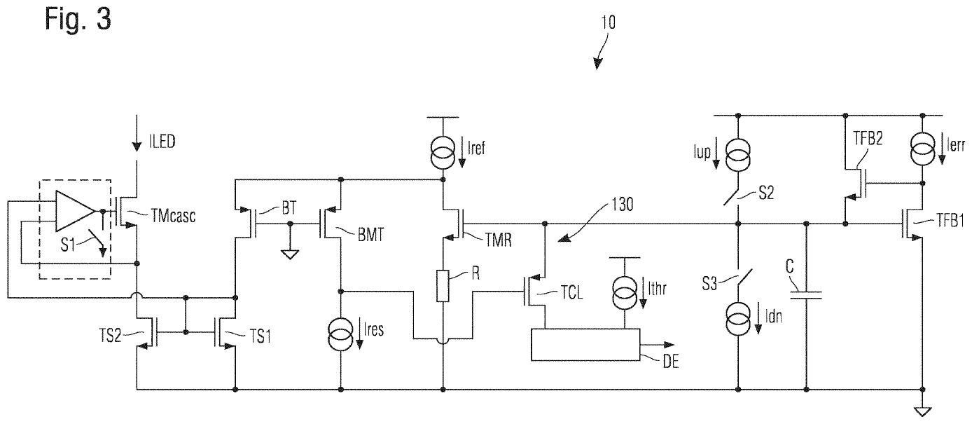

The object of the present invention is also solved by a method for generating current pulses as shown in FIG. 4.

In step S100, a constant current Iref is generated.

In step S110, a current ramp is generated. The current ramp is subtracted from the constant current Iref to generate a supply current.

In step S120, the supply current is compared with a first current value Ires.

In step S130, the ramp generator is switched off when the supply current is smaller than or equal to the first current value Iref.

In another step, the supply current is supplied to the load 150 such as a LED.

In another step, a lower limit of the current ramp may be determined.

In a another step, the supply current of the first current value Ires may be supplied when the ramp generator 110 is switched off. As mentioned above, the first current value Ires may be set with high precision to a few μA.

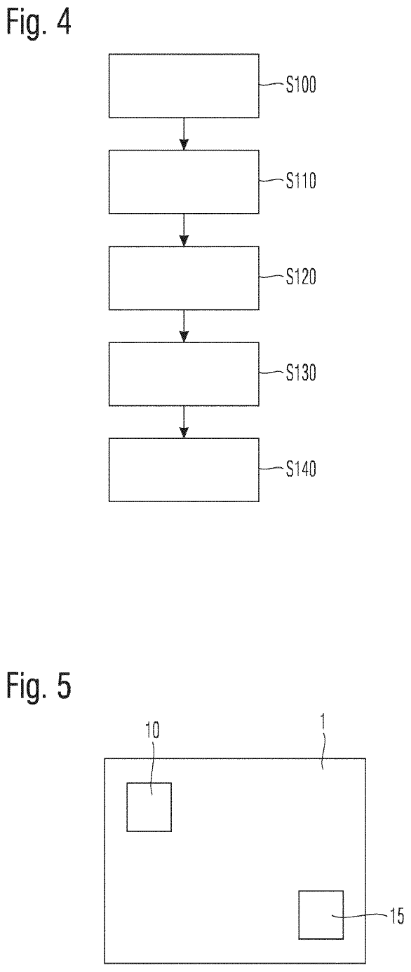

FIG. 5 illustrates a schematic diagram an electronic device 1 according to embodiments. It comprises a light emitting element 15 and the circuit 10 for generating current pulses as described above for supplying a current to the light emitting element 15.

In summary, the circuit 10 as shown in FIGS. 2 and 3 enables minimizing the dead-time and prevents distortions in the output current (such as sudden jumps) at a turn-on of the current output branch.

In addition, with said configurations area and design efforts are sufficiently saved.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

### LIST OF REFERENCES

1 illumination device
10 circuit for generating current pulses
15 light emitting element
100 current generator
110 ramp generator
120 comparing circuit
130 clamping switch
135 clamping circuit
140 supply circuit
150 load
Iref constant current
Ires first current value
Iup current
Idn current
Ierr current
Ithr current threshold
ITS1 current
V1 voltage
Vth voltage threshold
VTMR gate voltage
Vmax voltage
S1 Switch
S2 Switch
S3 Switch
R Resistor
C Capacitor
TMR transistor
TCL clamping transistor
TMcasc transistor
TFB1 transistor
TFB2 transistor
TS1 transistor
TS2 transistor
BT buffer transistor
BMT buffer mirror transistor
S100 generating a constant current
S110 generating a current ramp
S120 comparing the supply current with a first current value
S130 switching off a ramp generator when the supply current is smaller than or equal to the first current value
S140 supplying the supply current to a load (150)

1. A circuit for providing a supply current, comprising:
a current generator for generating a constant current;
a ramp generator for generating a current ramp, the current ramp being subtracted from the constant current to generate the supply current;
a comparing circuit for comparing the supply current with a first current value;
a clamping switch configured to switch off the ramp generator when the supply current is smaller than or equal to the first current value; and
a supply circuit for supplying the supply current to a load.

2. The circuit according to claim 1, further comprising a clamping circuit for determining a lower limit of the current ramp.

3. The circuit according to claim 1, wherein the comparing circuit comprises a sensing mirror comprising a buffer transistor and a buffer mirror transistor, the buffer transistor being connected in series to the supply circuit and the buffer mirror transistor being connected via a connection node to a current source supplying current of the first current value.

4. The circuit according to claim 3, wherein the clamping switch comprises a clamping transistor, a gate of the clamping transistor being connected to the connection node.

5. The circuit according to claim 1, being configured to supply the supply current of the first current value when the ramp generator is switched off, wherein the first current value is set with high precision to a few μA.

6. The circuit according to claims 1, wherein the supply circuit further comprises a supply switching element for turning off the supply current when the supply current is smaller than or equal to the first current value.

7. The circuit according to claim 6, further comprising a driving element for driving the supply switching element and being coupled to the clamping switch.

8. A method for providing a supply current, comprising:
generating a constant current;
generating a current ramp, the current ramp being subtracted from the constant current to generate the supply current;
comparing the supply current with a first current value;
switching off a ramp generator when the supply current is smaller than or equal to the first current value; and
supplying the supply current to a load.

9. The method according to claim 8, further comprising:
determining a lower limit of the current ramp.

10. The method according to claim 8, further comprising:
supplying the supply current of the first current value when the ramp generator is switched off, wherein the first current value is set with high precision to a few μA.

11. An illumination device comprising a light emitting element and a circuit for providing a supply current to the light emitting element, the circuit comprising:
a current generator for generating a constant current;
a ramp generator for generating a current ramp, the current ramp being subtracted from the constant current to generate the supply current;
a comparing circuit for comparing the supply current with a first current value;
a clamping switch configured to switch off the ramp generator when the supply current is smaller than or equal to the first current value; and
a supply circuit for supplying the supply current to a load.
